(19) United States
(12) Patent Application Publication
(10) Pub. No.: US 2009/0057742 A1
(43) Pub. Date: Mar. 5, 2009

(54) CMOS VARACTOR

(76) Inventors: Sungjae Lee, Burlington, VT (US); Scott keith Springer, Burlington, VT (US)

Correspondence Address: SCHMEISER, OLSEN & WATTS, 22 CENTURY HILL DRIVE, SUITE 302, LATHAM, NY, 12110, US

(21) Appl. No.: 11/847,378

(22) Filed: Aug. 30, 2007

(51) Int. Cl. H01L 29/94; H01L 21/8238

(52) U.S. Cl. 257/312; 438/199; 257/E21.632; 257/E29.345

(57) ABSTRACT

A varactor and method of fabricating the varactor. The varactor includes a silicon body in a silicon layer of an SOI substrate; a polysilicon electrode comprising a gate region and a plate region separated from the body by a gate dielectric layer, the gate and plate regions contiguous, the electrode electrically connected to a first pad; and a source formed in the body on a first side of the gate region, a drain formed in the body on a second and opposite side of the gate region, and a body contact formed in the body on a side of the plate region away from the gate region, the source, drain and body contact, separated from each other by regions of the body under the electrode, the source, drain and body contact electrically connected to each other and to a second pad.

### FIELD OF THE INVENTION

The present invention relates to the field of integrated circuits; more specifically, it relates to CMOS varactor structure.

### BACKGROUND OF THE INVENTION

Varactors are extensively used in voltage controlled oscillators used for generating clock signals in integrated circuits. Current integrated circuit varactors have limited tuning ranges which limit the performance of voltage controlled oscillators. Current integrated circuit varactors are difficult to integrate into CMOS technology, especially CMOS technology using SOI substrate thus adding additional costs to the manufacturing process. Accordingly, there exists a need in the art to overcome the deficiencies and limitations described hereinabove.

### SUMMARY OF THE INVENTION

A first aspect of the present invention is a varactor, comprising: a substrate comprising a single-crystal upper silicon layer separated from a lower silicon layer by a buried oxide layer; dielectric isolation abutting sidewalls of a region of the upper silicon layer and thereby defining a body in the upper silicon layer, the dielectric isolation extending from a top surface of the substrate to a top surface of the buried oxide layer; a polysilicon electrode comprising a gate region and a plate region separated from the body by a gate dielectric layer, the gate and plate regions contiguous, the electrode electrically connected to a first pad; and a source formed in the body on a first side of the gate region, a drain formed in the body on a second and opposite side of the gate region, and a body contact formed in the body on a side of the plate region away from the gate region, the source, drain and body contact, separated from each other by regions of the body under the electrode, the source, drain and body contact electrically connected to each other and to a second pad.

A second aspect of the present invention is a method of fabricating a varactor, comprising: forming dielectric isolation abutting sidewalls of a region of a single crystal upper silicon layer of a substrate and thereby defining a body in the upper silicon layer, the substrate comprising the upper silicon layer separated from a lower silicon layer by a buried oxide layer, the dielectric isolation extending from a top surface of the substrate to a top surface of the buried oxide layer; forming a polysilicon electrode comprising a gate region and a plate region separated from the body by a gate dielectric layer, the gate and plate regions contiguous; electrically connecting the electrode to a first pad; forming a source in the body on a first side of the gate region, a drain in the body on a second and opposite side of the gate region, and a body contact in the body on a side of the plate region away from the gate region, the source, drain and body contact, separated from each other by regions of the body under the electrode; and electrically connecting the source, drain and body contact to each other and to a second pad.

### BRIEF DESCRIPTION OF THE DRAWINGS

The features of the invention are set forth in the appended claims. The invention itself, however, will be best understood by reference to the following detailed description of an illustrative embodiment when read in conjunction with the accompanying drawings, wherein:

FIG. 1 is a top view of a varactor structure according to embodiments of the present invention;

FIG. 2 is a cross-section through line 2-2 of FIG. 1;

FIG. 3 is a cross-section through line 3-3 of FIG. 1;

FIG. 4 is a top view of the varactor structure of FIG. 1 illustrating how the varactor is wired according to embodiments of the present invention; and

FIG. 5 is a plot of capacitance vs. voltage for a typical varactor according to the embodiments of the present invention.

### DETAILED DESCRIPTION OF THE INVENTION

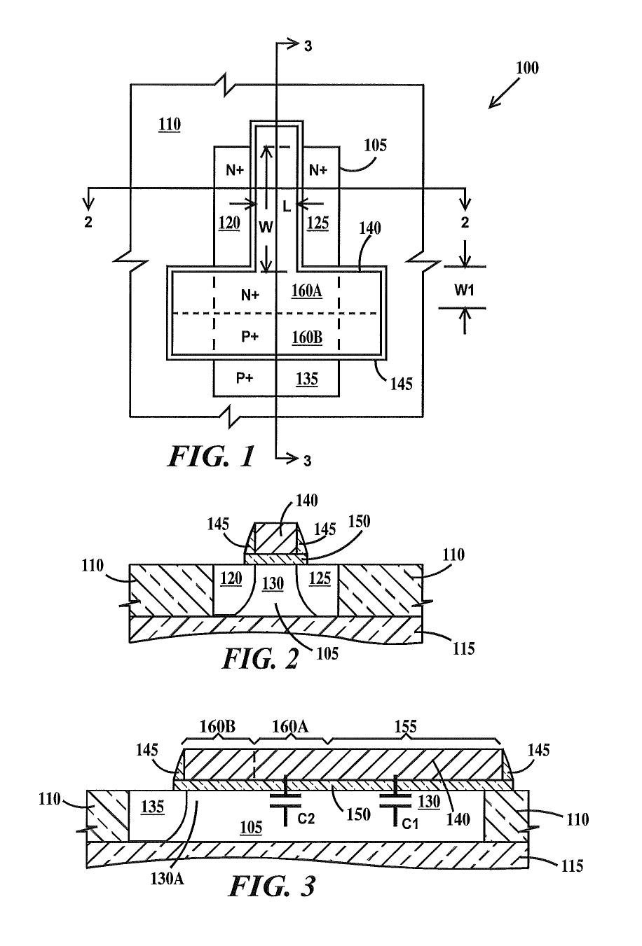

FIG. 1 is a top view, FIG. 2 is a cross-section through line 2-2 of FIG. 1, and FIG. 3 is a cross-section through line 3-3 of FIG. 1 of a varactor structure according to embodiments of the present invention. In FIGS. 1, 2 and 3, a varactor 100 includes a single-crystal silicon body 105 whose perimeter is surrounded by dielectric isolation 1 10. Body 105 is formed from an upper silicon layer of a silicon-on-insulator (SOI) substrate on a top surface of a buried oxide (BOX) layer 115 of the SOI substrate. A bottom surface of BOX layer 115 abuts a lower silicon layer (not shown) of the SOI substrate. Dielectric isolation 110 extends from a top surface of dielectric isolation that is substantially coplanar with a top surface of body 105 and the top surface of BOX layer 115.

Formed in body 105 is a source region 120 and a drain region 125 separated by a channel region 130 of body 105. A body contact region 135 is also formed in body 105. An extension region 130A of channel region 130 (see FIG. 3) intervenes between body contact region 135 and source region 120 and drain region 125. Thus, source region 120, drain region 125 and body contact region 135 do not physically abut but are separated by regions of body 105. A polysilicon electrode 140 is formed over channel region 130 and extension region 130A. Dielectric spacers 145 are formed on the sidewalls of electrode 140, and electrode 140 and spacers 145 are separated from body region 130 and extension region 130A by a gate dielectric layer 150.

Electrode 140 comprises three contiguous portions, a gate 155 and plates 160A and 160B. The portion of varactor 100 comprising source 120, drain 125 and gate 155 has a channel length L measured between the source and the drain and a channel width W measured perpendicular to the channel length. There is a capacitance C1 between gate 155 and channel region 130. C1 also includes fringe field capacitance not shown. Plate 160A has a width W1 measured in the same direction as the channel width W of the FET first capacitor. There is a capacitance C2 between plate 160A and body 105. C2 also includes fringe field capacitance not shown. All other geometries fixed, the value of C2 is a function of W1. The greater W1, the greater C2.

In FIG. 1, source 120, drain 125, gate 155, and plate 160A are doped N-type, body contact 135 and plate 160B are doped P-type. Body 105 and thus channel region 130 and extension region 130A are doped P-type. The doping level of body 105 is at least an order of magnitude lower than the doping levels of source 120, drain 125, body contact 135, gate 155, and plates 160A and 160B. Alternatively, source 120, drain 125, gate 155, and plate 160A are doped P-type, body contact 135 and plate 160B are doped N-type. Body 105 and thus channel region 130 and extension region 130A are doped N-type. Again, the doping level of body 105 is at least an order of magnitude lower than the doping levels of source 120, drain 125, body contact 135, gate 155, and plates 160A and 160B.

Fabrication of varactor 100 utilizes conventional complimentary metal-oxide-silicon (CMOS) technology. A simplified process flow would include: (1) forming dielectric isolation 110 in an upper layer of a silicon layer of a SOI substrate and thus defining body 105, (2) forming gate dielectric layer 150 and lithographically defining and then etching electrode 140, (3) forming spacers 145, (4) masking body contact 135 and plate region 160B and simultaneously ion implanting source region 120, drain region 125, gate 155 and plate 160A, (5) masking source region 120, drain region 125, gate 155 and plate 160A and simultaneously ion implanting body contact region 135 and plate 160B, and (6) after removing the gate dielectric not protected by electrode 140 and spacers 145 forming a metal silicide layer (not shown in FIGS. 1, 2 and 3) on source 120, drain 125, body contact 135 and electrode 140.

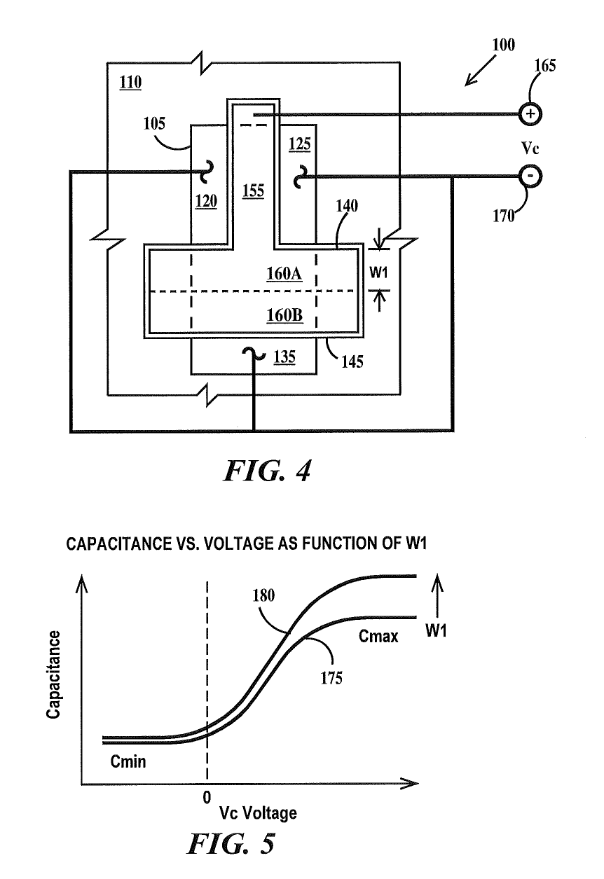

FIG. 4 is a top view of the varactor structure of FIG. 1 illustrating how the varactor is wired according to embodiments of the present invention. In FIG. 4, electrode 140 of varactor 100 is connected to a pad 165 that is connected to the positive terminal of a voltage control (Vc) power supply and source 120, drain 125 and body contact 135 to a pad 170 that is connected to the negative terminal of the Vc power supply. The capacitance of varactor 100 is measured between pads 165 and 170. The connections are made by subsequently formed interconnected wires in one or more stacked dielectric layers as is well known in the art.

FIG. 5 is a plot of capacitance vs. voltage for a typical varactor according to the embodiments of the present invention. In FIG. 5, curve 175 simulates capacitance versus Vc for a first varactor and curve 180 for a second varactor. The first and second varactors are identical except for the value of W1 (see FIG. 4) being greater for the second varactor. It can be seen from FIG. 5, that the maximum capacitance Cmax and the minimum capacitance Cmin of varactor are both a function of the magnitude of Vc. However, the value of Cmax is also a function of W1, while Cmin is substantially insensitive to the value of W1. The capacitance C of varactor 100 (see FIG. 4) is equal to C1+C2 (see FIG. 3). Since the frequency of an oscillator is the one over the square root of LC, where L is the inductance of the oscillator, the frequency can be controlled by varying C. The range of C, which in turn can be controlled by Vc, is determined by W1. Varactors can be rated in terms of the Cmax/Cmin ratio. For varactor according to the embodiments of the present invention the Cmax/Cmin ratio is a function of W1. Since Cmax/Cmin is a function of W1, Cmax/Cmin is also a function of the area of plate 160A (see FIG. 4). The area of plate 160B adds no significant capacitance since varactor 100 is operated in inversion mode and the values of Cmin and Cmax are substantially insensitive to the area of plate 160B. The value of W1 is determined by the photomask used in the lithographic step used to define the geometry of electrode 140 (see FIG. 4) and the block photomask used to define the boundary of dopant in plates 1 60A and 1 60B.

Thus, the embodiments of the present invention overcome the deficiencies and limitations described hereinabove by utilizing a body contacted field-effect transistor in SOI technology as a varactor with high tenability and virtually no CMOS integration issues.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A varactor, comprising:
a substrate comprising a single-crystal upper silicon layer separated from a lower silicon layer by a buried oxide layer;
dielectric isolation abutting sidewalls of a region of said upper silicon layer and thereby defining a body in said upper silicon layer, said dielectric isolation extending from a top surface of said substrate to a top surface of said buried oxide layer;
a polysilicon electrode comprising a gate region and a plate region separated from said body by a gate dielectric layer, said gate and plate regions contiguous, said electrode electrically connected to a first pad; and
a source formed in said body on a first side of said gate region, a drain formed in said body on a second and opposite side of said gate region, and a body contact formed in said body on a side of said plate region away from said gate region, said source, drain and body contact, separated from each other by regions of said body under said electrode, said source, drain and body contact electrically connected to each other and to a second pad.

2. The varactor of claim 1, wherein a maximum capacitance of said varactor is a function of an area of said plate region and a minimum capacitance of said varactor is substantially insensitive to said area of said plate region.

3. The varactor of claim 1, wherein said source, said drain, said gate region and a first region of said plate region are doped N-type and said body, said body contact and a second region of said plate region are doped P-type, a doping level of said body at least an order of magnitude less than a doping level of said body contact or a doping level of said source and said drain.

4. The varactor of claim 1, wherein said source, said drain, said gate region and a first region of said plate region are doped P-type and said body, said body contact and a second region of said plate region are doped N-type, a doping level of said body at least an order of magnitude less than a doping level of said body contact or a doping level of said source and said drain.

5. The varactor of claim 1, wherein:
said body has first and second sidewalls parallel to said first and second sides of said gate region and opposite first and second ends, said source and said drain extend along opposite sidewalls of said body and abutting said first end of said body, said body contact extending along said second end of said body and abutting said first and second sides of said body.

6. The varactor of claim 5, wherein:
said electrode comprises a first region having a first major axis parallel to said first and second sides of said gate region, a second region having a second major axis and a third region having a third major axis, said second and third major axes perpendicular to said first major axis, said first, second, and third regions contiguous, said second region intervening between said first and third regions, said gate region comprising said first region and said plate region comprising said second and third regions.

7. The varactor of claim 6, wherein a maximum capacitance of said varactor is a function of an area of said second region and substantially insensitive to an area of said third region and a minimum capacitance of said varactor is substantially insensitive to said areas of said second and third regions.

8. A method of fabricating a varactor, comprising:
forming dielectric isolation abutting sidewalls of a region of a single crystal upper silicon layer of a substrate and thereby defining a body in said upper silicon layer, said substrate comprising said upper silicon layer separated from a lower silicon layer by a buried oxide layer, said dielectric isolation extending from a top surface of said substrate to a top surface of said buried oxide layer;
forming a polysilicon electrode comprising a gate region and a plate region separated from said body by a gate dielectric layer, said gate and plate regions contiguous;
electrically connecting said electrode to a first pad;
forming a source in said body on a first side of said gate region, a drain in said body on a second and opposite side of said gate region, and a body contact in said body on a side of said plate region away from said gate region, said source, drain and body contact, separated from each other by regions of said body under said electrode; and
electrically connecting said source, drain and body contact to each other and to a second pad.

9. The method of claim 8, wherein a maximum capacitance of said varactor is a function of an area of said plate region and a minimum capacitance of said varactor is substantially insensitive to said area of said plate region.

10. The method of claim 8, further including:
simultaneously doping said source, drain, said gate region and a first region of said plate region N-type and simultaneously doping said body, said body contact and a second region of said plate region P-type, a doping level of said body at least an order of magnitude less than a doping level of said body contact or a doping level of said source and said drain.

11. The method of claim 8, further including:
simultaneously doping said source, drain and a first region of said gate region P-type; and;
simultaneously doping said body, said body contact, said plate region and a second region of said plate region N-type, a doping level of said body at least an order of magnitude less than a doping level of said body contact or a doping level of said source and said drain.

12. The method of claim 8, wherein:
said body has first and second sidewalls parallel to said first and second sides of said gate region and opposite first and second ends, said source and said drain extend along opposite sidewalls of said body and abutting said first end of said body, said body contact extending along said second end of said body and abutting said first and second sides of said body.

13. The varactor of claim 12, wherein:
said electrode comprises a first region having a first major axis parallel to said first and second sides of said gate region, a second region having a second major axis and a third region having a third major axis, said second and third major axes perpendicular to said first major axis, said first, second, and third regions contiguous, said second region intervening between said first and third regions, said gate region comprising said first region and said plate region comprising said second and third regions.

14. The varactor of claim 13, wherein a maximum capacitance of said varactor is a function of an area of said second region and substantially insensitive to an area of said third region and a minimum capacitance of said varactor is substantially insensitive to said areas of said second and third regions.
